(19) United States
(12) Patent Application Publication
(10) Pub. No.: US 2025/0072137 A1
(43) Pub. Date: Feb. 27, 2025

(54) LIGHT DETECTION DEVICE

(71) Applicant: SONY SEMICONDUCTOR SOLUTIONS CORPORATION, Kanagawa (JP)

(72) Inventors: Takayuki OGASAHARA, Kanagawa (JP); Kaito YOKOCHI, Kanagawa (JP); Koji MIYATA, Kanagawa (JP); Seiki TAKAHASHI, Kanagawa (JP); Hiroaki TAKASE, Kanagawa (JP)

(73) Assignee: SONY SEMICONDUCTOR SOLUTIONS CORPORATION, Kanagawa (JP)

(21) Appl. No.: 18/847,618

(22) PCT Filed: Mar. 28, 2023
(86) PCT No.: PCT/JP2023/012589

§ 371 Date: Sep. 16, 2024

(30) Foreign Application Priority Data
Apr. 4, 2022 (JP) 2022-062669

(51) Int. Cl. H01L 27/146

(52) U.S. Cl. CPC H01L 27/14607; H01L 27/14605; H01L 27/14621; H01L 27/14645

(57) ABSTRACT

A light detection device comprises a pixel array including a plurality of pixel units. At least one pixel unit of the plurality of pixel units includes a photoelectric conversion region and a light guide region that guides light to the photoelectric conversion region. For each pixel unit of the at least one pixel unit, the light guide region includes nanostructures that direct light to the photoelectric conversion region, and the nanostructures have at least one characteristic that varies based on a position of the pixel unit in the pixel array.

### CROSS REFERENCE TO RELATED APPLICATIONS

This application claims the benefit of Japanese Priority Patent Application JP 2022-062669 filed Apr. 4, 2022, the entire contents of which are incorporated herein by reference.

### TECHNICAL FIELD

The present disclosure relates to a light detection device.

### BACKGROUND ART

In a light detection device such as an image sensor in general, an incident light amount is lower on a peripheral edge side as compared with a center side of a photoelectric conversion region, which lowers sensitivity and an S/N ratio in the peripheral edge part and causes deterioration of an image quality. Even if an on-chip lens is disposed on a light-incident surface side of the photoelectric conversion region, lowering of the sensitivity of the peripheral edge part occurs. When the light transmitted through the on-chip lens forms an image on a light receiving surface in the photoelectric conversion region, the light amount is the largest and the brightest at an optical axis position, and the more it is separated away from the optical axis, the more the light amount is lowered and it darkens. This phenomenon is called lowering of a peripheral light amount, a shortage of the peripheral light amount or peripheral light reduction. The lowering of the peripheral light amount occurs in accordance with vignetting and cosine fourth rule.

On the other hand, an art of enabling taking-in of light from peripheral pixels by disposing nanostructures instead of the on-chip lens on the light incident surface side of a photodiode is proposed (see PTL 1). A light propagation direction can be controlled by controlling a shape or the like of the nanostructures.

### CITATION LIST

### Patent Literature

PTL 1: JP 2021-69119A

### SUMMARY

### Technical Problem

However, even if the nanostructures are disposed on the light incident surface side of the photodiode, there is a concern that the sensitivity is lowered on the peripheral edge side as compared with the center side of the photoelectric conversion region. Moreover, if the propagation direction of the light is controlled by the nanostructures, color mixture can occur easily, and there is a concern that the sensitivity is lowered. PTL 1 does not particularly refer to a measure for preventing lowering of the sensitivity on the peripheral edge side in the photoelectric conversion region and a measure against occurrence of the color mixture caused by the provision of the nanostructures.

Thus, this disclosure provides a light detection device which can suppress lowering of resolution while the sensitivity is improved when the nanostructures is used.

### Solution to Problem

In order to solve the problem described above, according to this disclosure, a light detection device is provided by including a pixel array including a plurality of pixel units, at least one pixel unit of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.

The plurality of pixel guide regions corresponding to the plurality of pixels may control the opening range by varying at least any one of a pitch diameter of the nanostructures, a pitch interval between the nanostructural bodies, a gap interval between the nanostructural bodies, and a number of the nanostructures in accordance with the image height.

Regarding the pixel guide region, the higher the image height is, the larger the opening range may be, and the lower the image height is, the smaller the opening range may be.

According to this disclosure, such a light detection device is provided by including a photoelectric conversion region having a plurality of pixels, and
a light guide region disposed closer to a light incident direction side than the photoelectric conversion region and controls a propagation direction of light to the photoelectric conversion region, in which
the light guide region has a pixel guide region having nanostructures for each of the plurality of pixels, and
each of the plurality of pixel guide regions corresponding to the plurality of pixels controls an opening range according to a light amount of the light incident to the corresponding pixel guide region by changing at least any one of a pitch diameter of the nanostructures, a pitch interval between the nanostructural bodies, a gap interval between the nanostructural bodies, and a number of the nanostructures in accordance with an image height.

The pixel guide region may be configured such that the higher the image height is, the larger amount of light may be propagated to the photoelectric conversion region, and the lower the image height is, the smaller amount of light may be propagated to the photoelectric conversion region.

It may be so configured that the photoelectric conversion region has a plurality of color pixels for each of the plurality of pixels,
the light guide region has the pixel guide region for each of the plurality of color pixels, and
the pixel guide region controls the propagation direction of the light in the light amount according to a wavelength of incident light and the image height.

The pixel guide region may vary a change rate of the incident light amount with respect to a change in the image height depending on the wavelength of the incident light.

Each of the plurality of pixel guide regions corresponding to the plurality of color pixels included in one pixel may control the opening range on the basis of a difference in the number of the color pixels by color in the one pixel.

It may be so configured that the pixel guide region corresponding to the smaller number of color pixels by color in the one pixel has larger opening range so that a larger light amount is transmitted.

It may be so configured that a color filter region disposed correspondingly to the plurality of color pixels is provided between the light guide region and the photoelectric conversion region,
the color filter region has a plurality of color filter portions for each pixel, and
the pixel guide region may control the opening range on the basis of the difference in the numbers by color of the plurality of color filter portions.

The plurality of pixel guide regions corresponding to the plurality of pixels may vary materials of the nanostructural bodies in accordance with the image height.

The nanostructures have
a plurality of columnar members disposed separately from each other along the light incident surface, and
a base member that covers a periphery of the plurality of columnar members, in which in the plurality of pixel guide regions corresponding to the plurality of pixels, a material of at least either one of the columnar member and the base member may be different in accordance with the image height.

In the plurality of pixel guide regions corresponding to the plurality of pixels, pupil correction to the incident light may be performed at least in some of the pixel guide regions.

It may be so configured that the closer to a peripheral side than a center side in the light guide region the pixel guide region is located, the larger a pupil correction amount is set.

It may be so configured that the pupil correction is performed by shifting the pixel guide region in the light guide region along the light incident surface with respect to the corresponding pixel in the photoelectric conversion region, and
the closer to the peripheral side than the center side in the light guide region the pixel guide region is located, the larger the amount by which the pixel guide region in the light guide region is shifted with respect to the corresponding pixel in the photoelectric conversion region is set.

It may be so configured that the pupil correction is performed by shifting the pixel guide region in the light guide region along the light incident surface with respect to the corresponding color filter portion in the color filter region, and
the closer to the peripheral side than the center side in the light guide region the pixel guide region is located, the larger the amount by which the pixel guide region in the light guide region is shifted with respect to the corresponding color filter portion in the color filter region is set.

The light guide region has
a first light control portion having first nanostructures and
a second light control portion laminated on the first light control portion and having second nanostructures, in which
the first light control portion and the second light control portion have pixel guide regions having nanostructural bodies for each of the plurality of pixels,
the pupil correction is performed by shifting the pixel guide region in the first light control portion along the light incident surface with respect to the corresponding pixel guide region in the second light control portion, and
the closer to the peripheral side than the center side in the light guide region the pixel guide region is located, the larger the amount by which the pixel guide region in the first light control portion is shifted with respect to the corresponding pixel guide region in the second light control portion is set.

### BRIEF DESCRIPTION OF DRAWINGS

FIG. 1 is a block diagram illustrating a schematic configuration of a light detection device according to an embodiment of this disclosure.

FIG. 2 is a diagram for explaining a principle of nanostructures.

FIG. 3A is a diagram illustrating a light incident direction to a photoelectric conversion region when a lens is disposed on a light incident surface side of the photoelectric conversion region.

FIG. 3B is a diagram illustrating the light incident direction to the photoelectric conversion region when a light guide region is provided between the lens and the photoelectric conversion region.

FIG. 4 is a diagram illustrating a relationship between an image height and brightness.

FIG. 5 is a schematic sectional view of the light detection device 1 according to this embodiment.

FIG. 6 illustrates diagrams for explaining a color splitter.

FIG. 7A is a plan view schematically illustrating a state where each pixel guide region corresponding to each color pixel in the color splitter takes in light from a periphery.

FIG. 7B is a view subsequent to FIG. 7A.

FIG. 7C is a view subsequent to FIG. 7B.

FIG. 8A is a diagram illustrating a relationship between an opening of the color splitter and sensitivity.

FIG. 8B is a diagram illustrating a relationship between the opening of the color splitter and resolution.

FIG. 9 is a plan view schematically illustrating opening ranges for a red pixel and a blue pixel.

FIG. 10 is a diagram in which circles indicating the opening ranges of FIG. 9 are aligned along a radial direction.

FIG. 11 shows diagrams illustrating the opening range in a sectional direction of the light detection device from a center part to a peripheral edge part of the color splitter.

FIG. 12 is a plan view schematically illustrating the opening range for a green pixel.

FIG. 13 is a diagram in which circle indicating the opening ranges in FIG. 12 are aligned along the radial direction.

FIG. 14 shows diagrams illustrating an opening range 16 in the sectional direction of the light detection device from the center part to the peripheral edge part of the color splitter.

FIG. 15 illustrates diagrams for explaining the pupil correction in more detail.

FIG. 16 is a diagram illustrating an example of the pupil correction when a light-shielding wall is provided.

FIG. 17 illustrates a plan view and a sectional view of the nanostructures in the color splitter.

FIG. 18A is a plan view for explaining a pitch diameter, a pitch interval, and a gap interval of a pillar portion.

FIG. 18B is a sectional view for explaining a pillar height.

FIG. 19A is a plan view illustrating a first example of the nanostructures in the color splitter.

FIG. 19B is a plan view illustrating a second example of the nanostructures in the color splitter.

FIG. 19C is a plan view illustrating a third example of the nanostructures in the color splitter.

FIG. 20 is a block diagram illustrating an example of a schematic configuration of a vehicle control system.

FIG. 21 is an explanatory view illustrating an example of installation positions of a vehicle-exterior information detection portion and an image pickup portion.

### DESCRIPTION OF EMBODIMENTS

Hereinafter, an embodiment of the light detection device will be described with reference to the drawings. Though major constituent parts of the light detection device will be explained below, there can be constituent parts or functions in the light detection device, which are not shown or explained. The following explanation does not exclude the constituent parts or functions not shown or explained.

### (Schematic Configuration of Image Pickup Device)

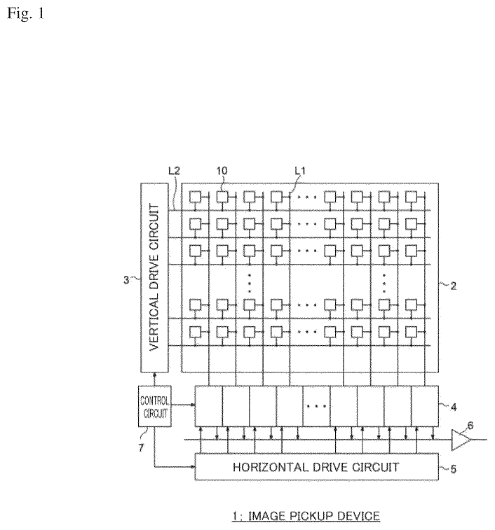

FIG. 1 is a block diagram illustrating a schematic configuration of a light detection device 1 according to an embodiment of this disclosure. The light detection device 1 in FIG. 1 illustrates a schematic configuration of an image sensor, that is, an image pickup device. Note that the light detection device 1 according to this embodiment can be applied also to devices including a light detection function other than the image sensor, that is, a device including a ToF (Time of Flight) function or a photon count function or the like, for example.

The light detection device 1 in FIG. 1 includes a pixel array portion 2, a vertical drive circuit 3, a column-signal processing circuit 4, a horizontal drive circuit 5, an output circuit 6, and a control circuit 7.

The pixel array portion 2 has a plurality of pixel units 10 disposed in a row direction and in a column direction, a plurality of signal lines L1 extending in the column direction, and a plurality of row selection lines L2 extending in the row direction. The pixel unit 10 has, though not shown in FIG. 1, a photoelectric conversion portion and a read-out circuit that reads out a pixel signal corresponding to a photoelectrically converted electric charge to the signal line L1. The pixel array portion 2 is a laminated body in which a photoelectric conversion region with the photoelectric conversion portion disposed in a two-dimensional direction and a read-out circuit region with the read-out circuit disposed in the two-dimensional direction are laminated.

The vertical drive circuit 3 drives the plurality of row selection lines L2. Specifically, the vertical drive circuit 3 line-sequentially selects each of the row selection lines L2 by line-sequentially supplying a drive signal to the plurality of row selection lines L2.

To the column-signal processing circuit 4, the plurality of signal lines L1 extending in the column direction are connected. The column-signal processing circuit 4 analog-digital (AD) converts the plurality of pixel signals supplied through the plurality of signal lines L1. In more detail, the column-signal processing circuit 4 compares the pixel signal on each of the signal lines L1 with a reference signal and generates a digital pixel signal on the basis of time until the signal levels of the pixel signal and the reference signal match each other. The column-signal processing circuit 4 sequentially generates a digital pixel signal (P-phase signal) at a reset level of a floating diffusion layer in the pixel and a digital pixel signal (D-phase signal) at a pixel signal level and performs correlated double sampling (CDS: Correlated Double Sampling).

The horizontal drive circuit 5 controls timing at which an output signal of the column-signal processing circuit 4 is transferred to the output circuit 6.

The control circuit 7 controls the vertical drive circuit 3, the column-signal processing circuit 4, and the horizontal drive circuit 5. The control circuit 7 generates the reference signal used for the column-signal processing circuit 4 to perform the AD conversion.

The light detection device 1 in FIG. 1 can be configured by laminating a first board on which the pixel array portion 2 and the like are disposed and a second board on which the vertical drive circuit 3, the column-signal processing circuit 4, the horizontal drive circuit 5, the output circuit 6, the control circuit 7 and the like are disposed by Cu—Cu connection, bump, via or the like.

A photodiode PD of each pixel in the pixel array portion 2 is disposed in the photoelectric conversion region. The image pickup device according to this embodiment includes, though not shown in FIG. 1, a light guide region (also called a light guide region herein) laminated in the photoelectric conversion region. The light guide region converts optical characteristics of incident light by using nanostructures as will be described later. For example, the light guide region can improve quantum efficiency Qe in the photoelectric conversion region by prolonging an optical path length of the incident light. It should be appreciated that although the description may refer to a particular region as a region that encompasses all pixel units 10, it may also be said that each pixel unit 10 or pixel 10c comprises the particular region. For example, the photoelectric conversion region 11 may be discussed as a region that encompasses all pixel units 10, and it may also be said that each pixel unit 10 comprises one or more photoelectric conversion regions 11 and/or that each pixel 10c comprises a photoelectric conversion region 11.

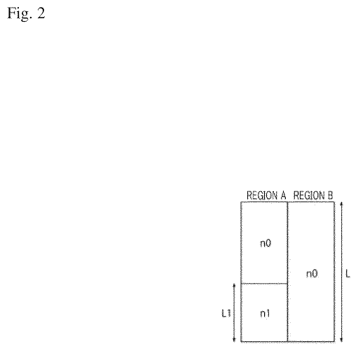

FIG. 2 is a diagram for explaining a principle of nanostructures 14. FIG. 2 shows an example in which a region A and a region B that transmit light, respectively, are adjacent to each other. The region A and the region B have a length L in a propagation direction of the light. A refractive index of the region B is n0. On the other hand, a part of the region A (L−L1) has a refractive index of n0, and the remaining L1 with the refractive index of n1.

An optical path length dA of the region A and an optical path length dB of the region B in FIG. 2 are expressed as in the following formula (1) and formula (2), respectively:

$$dA = n 0 \times ( L - L 1 ) + n 1 \times L 1 \\ dB = n 0 \times L \qquad ( 1 )$$

Thus, an optical-path length difference Δd between the region A and the region B is expressed by the following formula (3):

$$Δ d = dB - dA = L 1 ( n 0 - n 1 ) \qquad ( 3 )$$

Moreover, a phase difference φ between the region A and the region B is expressed by the following formula (4):

$$φ = 2 π L 1 ( n 0 - n 1 ) / λ \qquad ( 4 )$$

As shown in Formula (4), regarding the light propagating through the region A and the region B, the optical path length is changed in accordance with the refractive index difference between the region A and the region B, and a difference is generated in the propagating direction in accordance with the refractive index difference. The difference in the propagation direction depends on a wavelength of the light.

As described above, by causing the light to enter the nanostructures 14, the optical path length and the propagation direction of the light can be changed. The nanostructures 14 may include microstructures or nanostructures as pillars 14p. Moreover, as will be described later, by adjusting a width or a shape, direction, the number, and the like of structures of the nanostructures 14, the optical path length and the propagation direction of the light can be changed in various ways.

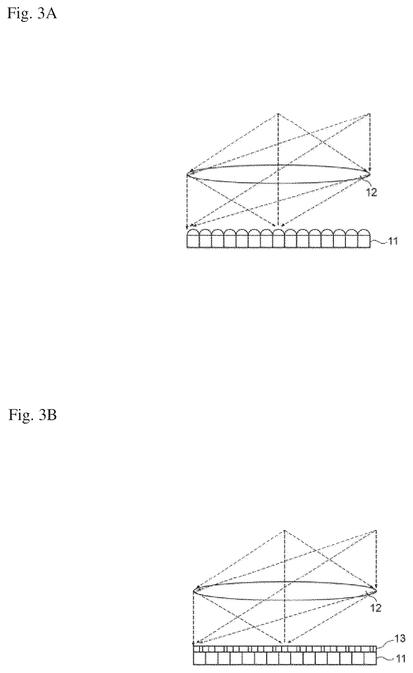

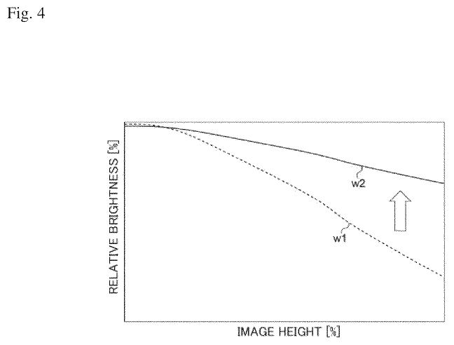

FIG. 3A is a diagram illustrating a light incident direction to the photoelectric conversion region 11 when the lens 12 is disposed on the light incident surface side of the photoelectric conversion region 11. FIG. 3B is a diagram illustrating the light incident direction to the photoelectric conversion region 11 when the light guide region 13 is provided between the lens 12 and the photoelectric conversion region 11. FIG. 4 is a diagram illustrating a relationship between the image height and the brightness in FIGS. 3A and 3B. A lateral axis in FIG. 4 is the image height [%] and a vertical axis is relative brightness [%]. Here, the image height is a distance in a radial direction from the optical-axis center position of the lens 12 to a subject light-incident position. A curve w1 in FIG. 4 denotes a brightness change with respect to the image height in FIG. 3A and a curve w2 denotes a brightness change with respect to the image height in FIG. 3B.

As shown in FIGS. 3A and 3B, a ratio of incidence of diagonal light is larger on the peripheral edge side of the lens 12 than the center side of the lens 12, that is, a side closer to the optical axis. Thus, as shown by the curve w1 in FIG. 4, the light amount incident to the photoelectric conversion region 11 is smaller on the peripheral edge side than on the center side. However, by providing the light guide region 13 having the nanostructures 14 between the lens 12 and the photoelectric conversion region 11 as in FIG. 3B, the light from peripheral pixels can be taken in as shown by the curve w2 in FIG. 4 and thus, the light amount on the peripheral edge side with the larger image height can be increased more than in the case in FIG. 3A, whereby the brightness can be improved.

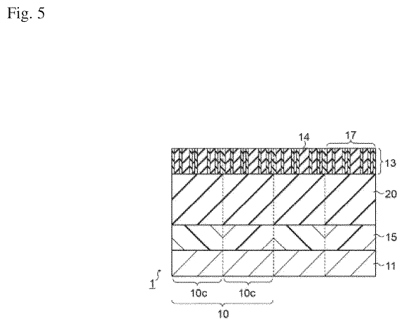

FIG. 5 is a schematic sectional view of the light detection device 1 according to this embodiment. The light detection device 1 according to this embodiment includes a structure in which the photoelectric conversion region 11, a color filter region 15 and the light guide region 13 are laminated.

The photoelectric conversion region 11 has a plurality of pixel units 10, each of which performs photoelectric conversion. Each pixel unit 10 is constituted by a plurality of color pixels 10c (10r, 10g, 10b). The photoelectric conversion region 11 has a photodiode for each of the color pixels 10c. Each pixel unit 10 may include four of the color pixels 10c in total, two each on vertical and lateral sides, in the case of a Bayer array. However, a pixel unit 10 may be comprised of more or fewer color pixels 10c (e.g., a pixel unit 10 includes one pixel 10c).

The color filter region 15 has a color filter portion that transmits light with a wavelength corresponding to each of the color pixels 10c. Since the one pixel unit 10 is constituted by a plurality of color pixels 10c, the color filter region 15 has a plurality of color filter portions for each of the pixels 10. The color filter portion transmits mainly the light in a wavelength band of the corresponding color.

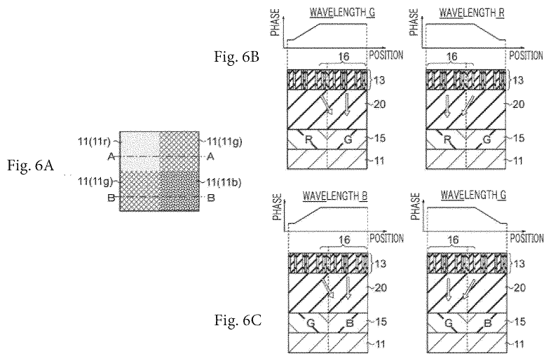

The light guide region 13 is disposed closer to the light incident direction side than the color filter region 15. The light guide region 13 has a pixel guide region (also called a pixel light guide region) 17 having the nanostructures 14 for each of the plurality of pixel units 10. In this description, the light guide region 13 is called a color splitter 13 or a light guide region in some cases. The pixel guide region 17 transmits light in the light amount within the opening range 16 (see FIGS. 6, which will be described later) according to the image height. As will be described later, the plurality of pixel guide regions 17 corresponding to the plurality of pixel units 10 control the opening range 16 by varying at least any one of the pitch diameter of the nanostructures 14, the pitch interval between the nanostructures 14, the gap interval between the nanostructures, and the number of the nanostructures 14 in accordance with the image height.

Between the light guide region 13 and the color filter region 15, an insulation layer 20 with light transparency is disposed. Moreover, on the light incident surface side of the light guide region 13, a reflection prevention film or a protective film, not shown, may be disposed.

The higher the image height is, the larger the pixel guide region 17 enlarges the opening range 16, while the lower the image height is, the smaller the pixel guide region 17 reduces the opening range 16.

The photoelectric conversion region 11 has a plurality of the color pixels 10c for each of the plurality of pixels 10. The color splitter 13 has the pixel guide region 17 for each of the plurality of color pixels 10c. The pixel guide region 17 transmits the light in the light amount according to the wavelength of the incident light and the image height.

The pixel guide region 17 varies a change rate of the incident light amount with respect to the change in the image height depending on the wavelength of the incident light. Each of the plurality of pixel guide regions 17 corresponding to the plurality of color pixels 10c included in the one pixel unit 10 controls the opening range 16 on the basis of a difference in the number of the color pixels 10c by color in the one pixel unit 10. The pixel guide region 17 corresponding to the smaller number of color pixels 10c by color in the one pixel unit 10, the larger the opening range 16 may be enlarged so as to transmit a larger amount of the light.

FIG. 6 are diagrams for explaining the color splitter 13 described above. In more detail, FIG. 6 are diagrams for explaining a function of the color splitter 13 when the color pixels 10c are disposed in the Bayer array in the photoelectric conversion region 11. In the Bayer array, the one pixel unit 10 is constituted by four types of the color pixels 10c. The four color pixels 10c include one red pixel 10r, two green pixels 10g, and one blue pixel 10b.

FIG. 6A is a plan view of the four color pixels 10c constituting the Bayer array. FIG. 6B is a sectional view in an A-A line direction in FIGS. 6A, and 6C is a sectional view in a B-B line direction of FIG. 6A. In the color splitter 13, a plurality of the columnar nanostructural bodies 14 are provided, and the opening ranges 16 that take in light are different in accordance with the wavelength of the light. In this description, each columnar member constituting each of the nanostructural bodies 14 is called a pillar portion 14p. The pillar portion 14p may have a columnar shape or a cubic shape. Moreover, each of the nanostructural bodies 14 may have a shape whose width in the height direction changes.

In the A-A line direction in FIG. 6A, as shown in FIG. 6B, the light with the green wavelength is taken in through the opening range 16 at an arrow root of the illustrated arrow and is received by the green pixel 10g, and the light with the red wavelength is taken in through the opening range 16 at the arrow root of the illustrated arrow and is received by the red pixel 10r. Similarly, in the B-B line direction in FIG. 6A, as shown in FIG. 6C, the light with the green wavelength is taken in through the opening range 16 at the arrow root of the illustrated arrow and is received by the green pixel 10g, and the light with the red wavelength is taken in through the opening range 16 at the arrow root of the illustrated arrow and is received by the red pixel 10r.

As described above, by providing the color splitter 13 constituted by the nanostructural bodies 14, the opening range 16 that takes in the light can be enlarged, and the light incident to the pixel guide region 17 corresponding to the pixel unit 10 adjacent thereto can be taken in.

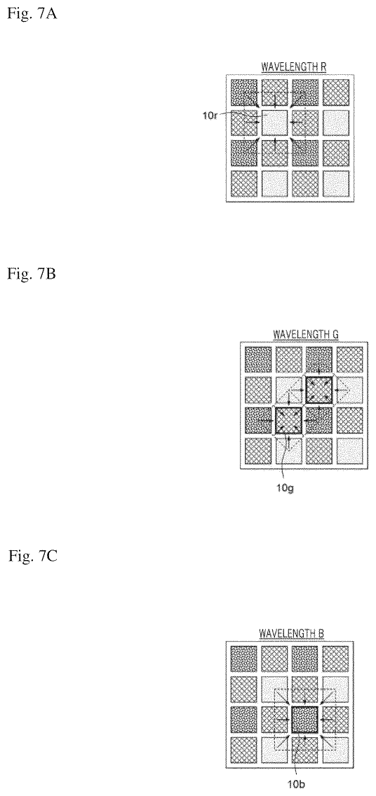

FIGS. 7A, 7B, and 7C are plan views schematically illustrating a state where each of the pixel guide regions 17 corresponding to each of the color pixels 10c in the color splitter 13 takes in the light from the periphery. The pixel guide region 17 corresponding to the red pixel 10r takes in, as shown in FIG. 7A, the light in the opening range 16 over the eight pixel guide regions 17 corresponding to the eight color pixels 10c in the periphery. There are two pixel guide regions 17 corresponding to the green pixel 10g in the one pixel 10, and the pixel guide region 17 corresponding to each of the green pixels 10g takes in, as shown in FIG. 7B, the color in the opening range 16 including the four color pixels 10c in the periphery. The blue pixel 10b takes in, as shown in FIG. 7C, the light in the opening range 16 over the eight pixel guide regions 17 corresponding to the eight color pixels 10c in the periphery.

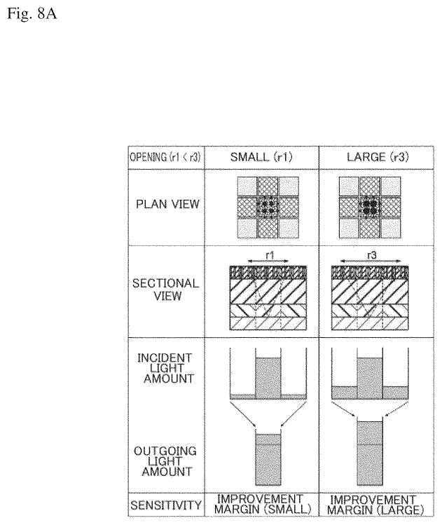

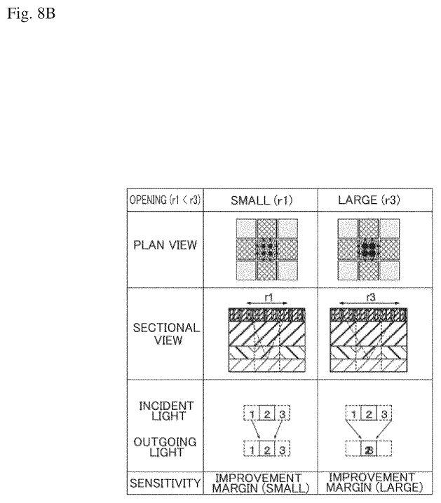

FIG. 8A is a diagram illustrating a relationship between an opening of the color splitter 13 and sensitivity. FIG. 8A shows a schematic plan view and sectional view of the color splitter 13, a relationship between the incident light amount to the color splitter 13 and an outgoing light amount from the color splitter 13, and the sensitivity for a case of the small opening range 16 (diameter: r1) and a case of the large opening range 16 (diameter: r3).

As shown in FIG. 8A, the smaller the opening range 16 of the color splitter 13 is, the larger light amount concentrates to the center part of each of the color pixels 10c, and the smaller an improvement margin of the sensitivity of each of the color pixels 10c becomes. On the other hand, the larger the opening range 16 of the color splitter 13 is, by the larger light amount in the peripheral edge part of each of the color pixels 10c can be increased, and the larger the improvement margin of the sensitivity of each of the color pixels 10c becomes.

FIG. 8B is a diagram illustrating a relationship between the opening of the color splitter 13 and the resolution. FIG. 8B shows a schematic plan view and sectional view of the color splitter 13, a relationship between a subject light image incident to the color splitter 13 and a subject light image outgoing from the color splitter 13, and the resolution for the case of the small opening range 16 and the case of the large opening range 16.

As shown in FIG. 8B, the smaller the opening range 16 is, the more unlikely color mixture between the adjacent color pixels 10c occurs. On the other hand, the larger the opening range 16 is, the more likely the color mixture between the adjacent color pixels 10c occurs.

As described above, the larger the opening range 16 of the color splitter 13 is made, the sensitivity can be improved, but the color mixture occurs more easily. Moreover, the smaller the opening range 16 is made, the sensitivity is lowered, but the color mixture does not occur easily. Thus, it is preferable that the opening range 16 is controlled in accordance with a position in the color splitter 13. More specifically, it is preferable that the closer to the center side of the color splitter 13, the smaller the opening range 16 is made, and the closer to the peripheral edge side, the larger the opening range 16 is made.

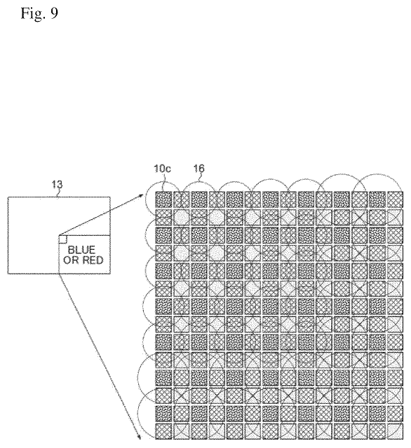

FIG. 9 is a plan view schematically illustrating the opening range 16 with respect to the red pixel 10r and the blue pixel 10b. In FIG. 9, the opening range 16 of the pixel guide region 17 corresponding to each of the color pixels 10c from the center part to the peripheral edge part of the color splitter 13 is schematically illustrated using circles.

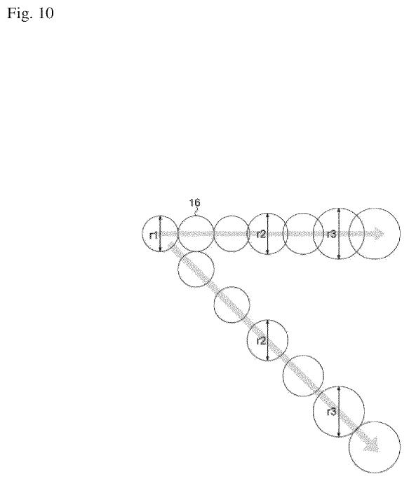

FIG. 10 is a diagram in which the circles indicating the opening ranges 16 in FIG. 9 are aligned along the radial direction. As shown in FIG. 10, the opening range 16 gradually becomes wider from the center part to the peripheral edge part of the color splitter 13. The wider the opening range 16 is, the more the light amount incident to the corresponding color pixel 10c increases, and the sensitivity is improved.

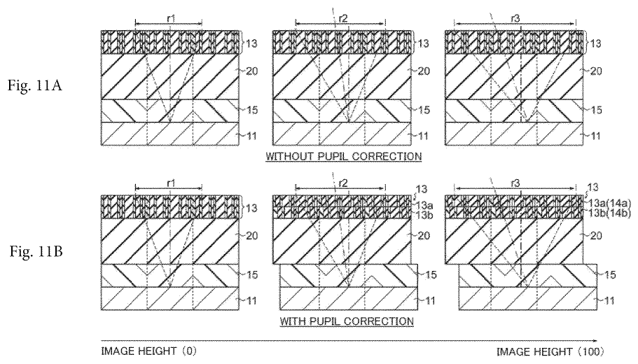

FIG. 11 are diagrams illustrating the opening range 16 in a sectional direction of the light detection device 1 from the center part to the peripheral edge part of the color splitter 13. FIG. 11A illustrates the opening range 16 (diameter r1, r2, r3 (r1<r2<r3)) of the pixel guide regions 17 corresponding to the color pixels 10c at three spots in FIG. 10. As shown in FIG. 11A, the wider the opening range 16 is, the larger light amount is incident to the corresponding color pixel 10c, and the sensitivity is improved.

To the peripheral edge part of the color splitter 13, more light is incident in a diagonal direction than to the center part. The nanostructures 14 in the color splitter 13 can change the propagation direction of the light from the diagonal direction, but only the nanostructures 14 are not sufficient. Thus, it is preferable to perform pupil correction which shifts a relative positional relationship between the color splitter 13 and the photoelectric conversion region 11.

FIG. 11B is a schematic sectional view of a case where the pupil correction is performed. In FIG. 11B, the position of the photoelectric conversion region 11 is shifted along a direction of the incident light to the color splitter 13 on the peripheral edge side of the photoelectric conversion region 11. As a result, even if the light is incident diagonally to the color splitter 13, the light can be caused to enter the corresponding color pixel 10c.

Note that, as shown in FIG. 11B, the closer to the center side of the photoelectric conversion region 11 (color splitter 13), the smaller a pupil correction amount becomes, and the closer to the peripheral edge side, the larger it becomes.

As described above, in this embodiment, the pupil correction can be performed by shifting the pixel guide region 17 in the light guide region 13 with respect to the corresponding pixel unit 10 in the photoelectric conversion region 11 along the light incident surface. The closer to the peripheral side than the center side of the light guide region 13 the pixel guide region 17 is located, the larger amount by which the pixel guide region 17 in the light guide region 13 is shifted is set with respect to the corresponding pixel unit 10 in the photoelectric conversion region 11. In more detail, the pupil correction is performed by shifting the pixel guide region 17 in the light guide region 13 with respect to the corresponding color filter portion in the color filter region 15 along the light incident surface. The closer to the peripheral side than the center side of the light guide region 13 the pixel guide region 17 is located, the larger amount by which the pixel guide region 17 in the light guide region 13 is shifted is set with respect to the corresponding color filter portion in the color filter region 15.

Moreover, as shown in FIG. 11B, a pupil correction effect can be improved by performing the pupil correction by constituting the color splitter 13 in a double-layer structure and by shifting a relative positional relationship of each layer along the light incident surface.

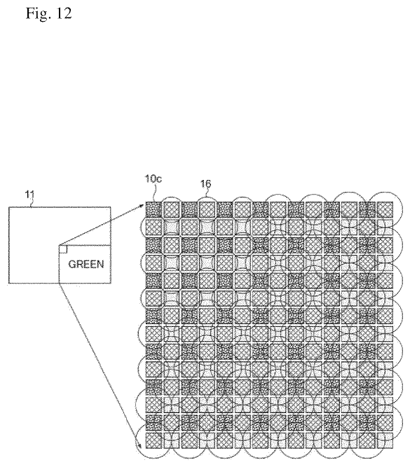

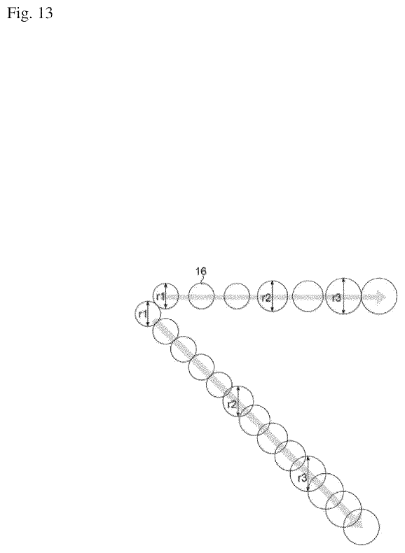

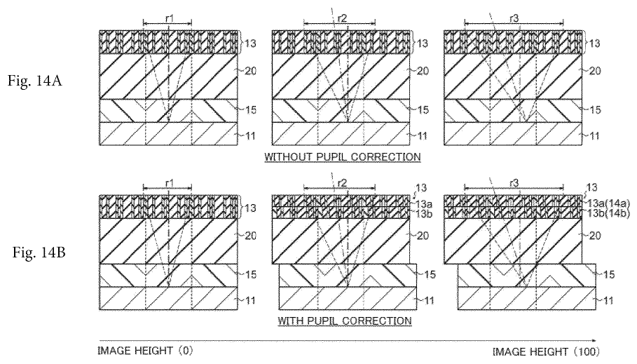

FIG. 12 is a plan view schematically illustrating the opening range 16 for the green pixel 10g. FIG. 13 is a diagram in which the circles indicating the opening ranges 16 in FIG. 12 are aligned along the radial direction. FIG. 14 are diagrams illustrating the opening range 16 in the sectional direction of the light detection device 1 from the center part to the peripheral edge part of the color splitter 13.

In the case of the Bayer array, there are two green pixels 10g in the one pixel 10, and the light amount is larger as compared with the other color pixels 10r, 10b. Thus, the opening range 16 of the green pixel 10g can be made smaller than the red pixel 10r and the blue pixel 10b. Thus, in FIGS. 12 and 13, a size of a circle indicating the opening range 16 is made smaller than the sizes of the circles in FIGS. 10 and 11. However, it is similar to the red pixel 10r and the blue pixel 10b in a point that the opening range 16 gradually widens from the center part to the peripheral edge part of the color splitter 13.

Moreover, even in the case of the green pixel 10g, more diagonal light is incident to the peripheral edge part of the color splitter 13 than to the center part and thus, pupil correction is preferably performed. FIG. 14A is a sectional view without the pupil correction, and FIG. 14B is a sectional view with the pupil correction. In FIG. 14B, the pupil correction amount is gradually increased from the center side to the peripheral edge side of the color splitter 13.

In FIGS. 11 and 14, the example in which the pupil correction is performed by shifting the relative positional relationship between the color splitter 13 and the color filter region 15 (photoelectric conversion region 11) along the light incident surface (hereinafter, referred to as first pupil correction), and the pupil correction is performed by making the color splitter 13 into double-layered and by shifting the relative positional relationship between each layer along the light incident surface (hereinafter, referred to as second pupil correction) was explained, but only either one of the first pupil correction and the second pupil correction may be performed.

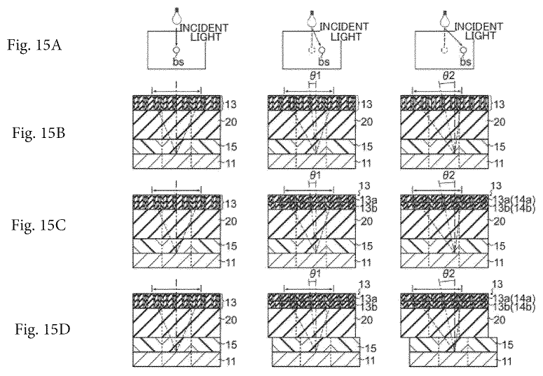

FIG. 15 are diagrams for explaining the pupil correction in more detail. FIG. 15 show the pupil correction in the case where the light is incident to the center part of the color splitter 13, the case in which the light is incident to a vicinity in the middle of the center part and the peripheral edge part of the color splitter 13, and the case in which the light is incident to the peripheral edge part of the color splitter 13.

FIG. 15A is a schematic plan view illustrating incident positions bs of the light to the color splitter 13. FIG. 15B is a schematic sectional view of the light detection device 1 when the pupil correction is not performed at three incident positions bs in FIG. 15A. FIG. 15C is a schematic sectional view of the light detection device 1 when the first example of the pupil correction is performed at the three incident positions bs in FIG. 15A. FIG. 15D is a schematic sectional view of the light detection device 1 when the second example of the pupil correction is performed at the three incident positions bs in FIG. 15A.

At the center part of the color splitter 13, since a ratio of the light incident from a normal direction of the light incident surface is larger, there is no need to perform the pupil correction. Thus, the sectional structures of FIGS. 15B to 15D are substantially the same.

In the vicinity of the middle position between the center part and the peripheral edge part of the color splitter 13, since the ratio of the light from the diagonal direction increases, the pupil correction is preferably performed. Thus, in FIG. 15C, the pupil correction is performed by making the color splitter 13 into the double-layered structure and by shifting the relative positional relationship between these two layers along the light incident surface.

In more detail, the color splitters 13 in FIGS. 11B, 14B, 15C, and 15D have a first light control portion (or first light guide portion) 13a and a second light control portion (or second light guide portion) 13b which are laminated. The first light control portion 13a and the second light control portion 13b have the nanostructures 14, respectively. In this description, the nanostructures of the first light control portion 13a is called first nanostructures 14a, and the nanostructures of the second light control portion 13b is called second nanostructures 14b in some cases. The pupil correction can be performed by shifting the relative positional relationship between the first light control portion 13a and the second light control portion 13b along the light incident surface.

In FIG. 15D, in addition to the pupil correction in FIG. 15C, the relative positional relationship between the color splitter 13 and the photoelectric conversion region 11 is shifted along the light incident surface. As a result, the pupil correction amount can be increased more than FIG. 15C.

When the color splitter 13 has a single-layered structure, since the pupil correction cannot be performed only by the color splitter 13, the pupil correction is performed by shifting the relative positional relationship between the color splitter 13 and the color filter region 15 (photoelectric conversion region 11) as shown in FIG. 15D.

Since the ratio of the light from the diagonal direction is further increased in the peripheral edge part of the color splitter 13, the need to perform the pupil correction is increased. Thus, in FIG. 15C, the pupil correction is performed by shifting the relative positional relationship between the first light control portion 13a and the second light control portion 13b in the color splitter 13 more largely. Moreover, in FIG. 15D, the pupil correction is performed by shifting the relative positional relationship between the color splitter 13 and the color filter region 15 (photoelectric conversion region 11) more largely in addition to the pupil correction in FIG. 15C.

The color splitter 13 has a light-shielding wall 18 (first light-shielding wall) on a boundary part of the pixel guide region 17 corresponding to the color pixel 10c in some cases. Similarly, the color splitter 13 provided in the photoelectric conversion region 11 has a light-shielding wall 19 (second light-shielding wall) on a boundary part of the color pixel 10c. By providing these light-shielding walls 18, 19, incidence of the light from the regions of the adjacent color pixels 10c can be prevented.

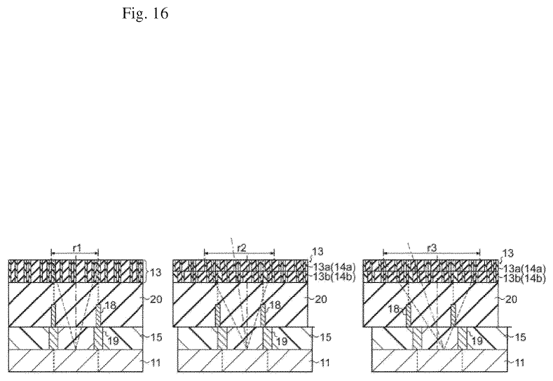

FIG. 16 is a diagram illustrating an example of the pupil correction when the aforementioned light-shielding walls 18, 19 are provided. FIG. 16 illustrates a sectional structure of the light detection device 1 on the center part, the middle part, and the peripheral edge part of the color splitter 13. In the center part of the color splitter 13, the relative positions of the light-shielding wall 18 in the color splitter 13 and the light-shielding wall 19 in the color filter region 15 are aligned in the lamination direction, but in the middle part, the relative positions of these light-shielding walls 18, 19 are somewhat shifted along the light incident surface. In the peripheral edge part, the relative positions of these light-shielding walls 18, 19 are shifted more largely.

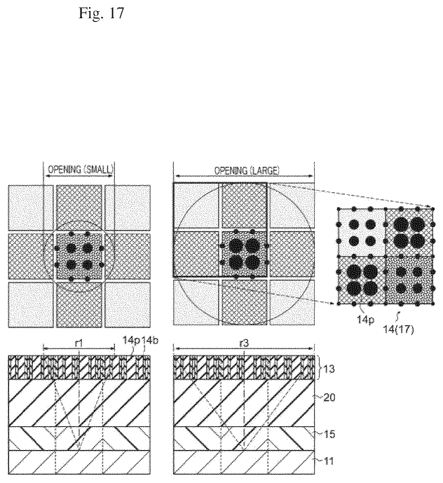

FIG. 17 are a plan view and a sectional view of the nanostructures 14 in the color splitter 13. The color splitter 13 is divided into the pixel guide regions 17 corresponding to each of the color pixels 10c, and each of the pixel guide regions 17 has the nanostructures 14. Each of the nanostructures 14 has a plurality of the pillar portions 14p, each extending in the lamination direction. The plurality of pillar portions 14p are surrounded by the base member 14b. A refractive index of the pillar portion 14p is larger than the refractive index of the base member 14b. A material of the pillar portion 14p is an insulating material such as TiO2, for example. More specifically, the pillar portion 14p is constituted by silicon compounds such as silicon nitride, silicon carbide and the like, metal oxides such as titanium oxide, tantalum oxide, niobium oxide, hafnium oxide, indium oxide, tin oxide, and the like or complex oxides of them. Other than the above, the pillar portion 14p may be constituted by organic substances such as siloxane. The material of the base member is an insulating material such as SiO2, for example.

The color splitter 13 controls the opening range 16 through which the light is transmitted by varying at least any one of the pitch diameter of the pillar portion 14p, the pitch interval between the pillar portions 14p, the gap interval between the pillar portions 14p, and the number of the pillar portion 14p in accordance with the image height for each of the pixel guide regions 17 corresponding to the color pixel 10c. Moreover, the color splitter 13 can control the opening range 16 by controlling at least any one of the material of the pillar portion 14p and the material of the base member 14b, the shape of the pillar portion 14p, the number of the pillar portions 14p, and a length in the lamination direction of the pillar portion 14p in accordance with the image height for each of the pixel guide regions 17 corresponding to the color pixel 10c.

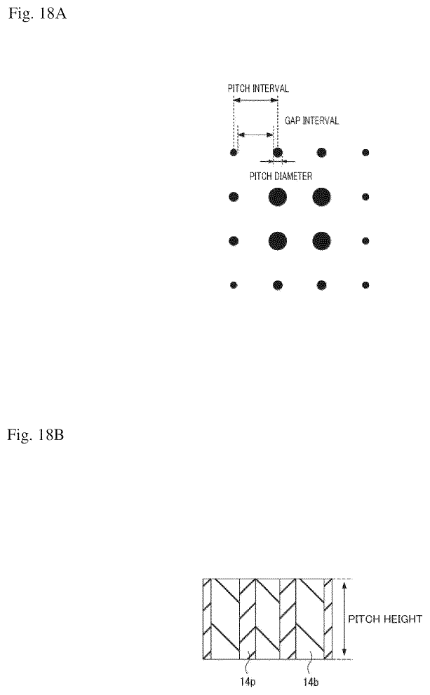

As described herein, at least one characteristic of the nanostructures (e.g., pillars 14p) of a light guide region 13 varies according to a position of a corresponding pixel unit 10 in the array of pixel units 10. In at least one embodiment and as discussed with reference to FIG. 18A, the at least one characteristic corresponds to a diameter of the nanostructures, a pitch of the nanostructures, a gap between two of the nanostructures, a material of the nanostructures, a number of the nanostructures, or any combination thereof. FIG. 18A is a plan view for explaining the pitch diameter, the pitch interval, and the gap interval of the pillar portions 14p, and FIG. 18B is a sectional view for explaining the pillar height. As shown in FIG. 18A, the pitch diameter (or diameter) is a diameter of a column, when the pillar portion 14p has a columnar shape. The pitch interval (or pitch) is the shortest distance between center positions of the two adjacent pillar portions 14p. The gap interval (or gap) between two adjacent pillar portions 14p is the shortest distance between outer peripheral surfaces of the two adjacent pillar portions 14p. As shown in FIG. 18B, the pillar height is a length in the lamination direction of the pillar portion 14p.

In the example in FIG. 17, the structures of the nanostructural bodies 14 of the red pixel 10r and the blue pixel 10b are made the same, and the structures of the nanostructural bodies 14 of the two blue pixels 10b in the Bayer array are made the same. Moreover, in the example in FIG. 17, the diameters of the pillar portions 14p of the green pixel 10g and the blue pixel 10b are made smaller than the diameter of the pillar portion 14p of the green pixel 10g. Furthermore, in the example in FIG. 17, the plurality of pillar portions 14p are disposed along the boundary of the pixel guide region 17.

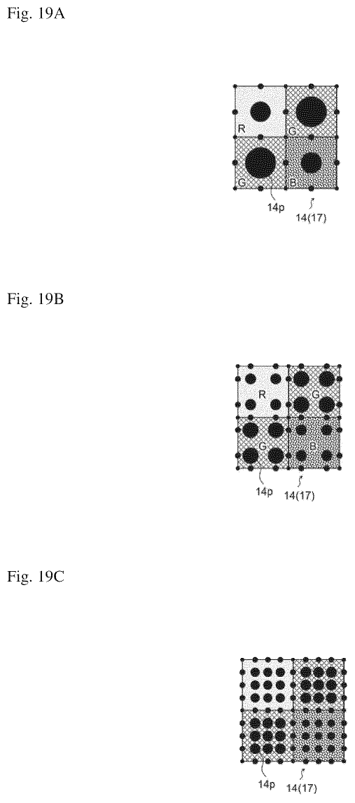

FIG. 17 is an example of the nanostructures 14, and various variations can be considered for the disposition of the pillar portion 14p. FIG. 19A is a plan view illustrating a first example of the nanostructures 14 in the color splitter 13. FIG. 19B is a plan view illustrating a second example of the nanostructures 14 in the color splitter 13. FIG. 19C is a plan view illustrating a third example of the nanostructures 14 in the color splitter 13.

In any one of FIGS. 19A, 19B, and 19C, the structures of the nanostructural bodies 14 in the pixel guide region 17 corresponding to the red pixel 10r and the green pixel 10g are the same. Moreover, the structures of the nanostructural bodies 14 in the pixel guide region 17 corresponding to the two green pixels 10g in the Bayer array are made the same. FIGS. 19A to 19C are examples of the nanostructures 14, and various variations can be considered.

As described above, in this embodiment, the pixel guide region 17 having the nanostructures 14 is provided for each of the pixel units 10 (e.g., for each of color pixels 10c) in the color splitter 13 disposed closer to the light incident direction side than the photoelectric conversion region 11 so that each of the pixel guide regions 17 transmits the light in the light amount in the opening range 16 according to the image height. As a result, the opening range 16 closer to the peripheral edge side than the center part of the color splitter 13 can be made larger, a drop in a peripheral light amount can be suppressed, and the sensitivity can be improved.

Moreover, on the center part side of the color splitter 13, the opening range 16 can be made smaller, and lowering of the resolution can be made less conspicuous. Thus, according to this embodiment, improvement of the sensitivity and prevention of lowering of the resolution can be both realized.

Moreover, in this embodiment, the pupil correction amount can be increased as it gets closer from the center side to the peripheral edge side of the color splitter 13, and appropriate pupil correction can be performed over the entire region of the photoelectric conversion region 11.

### Application Example

The art according to this disclosure can be applied to various products. For example, the art according to this disclosure may be realized as an apparatus to be mounted on any type of movable bodies such as an automobile, an electric vehicle, a hybrid-electric vehicle, a motorcycle, a bicycle, a personal mobility, an aircraft, a drone, a ship, a robot, a construction machine, an agricultural machine (tractor) and the like.

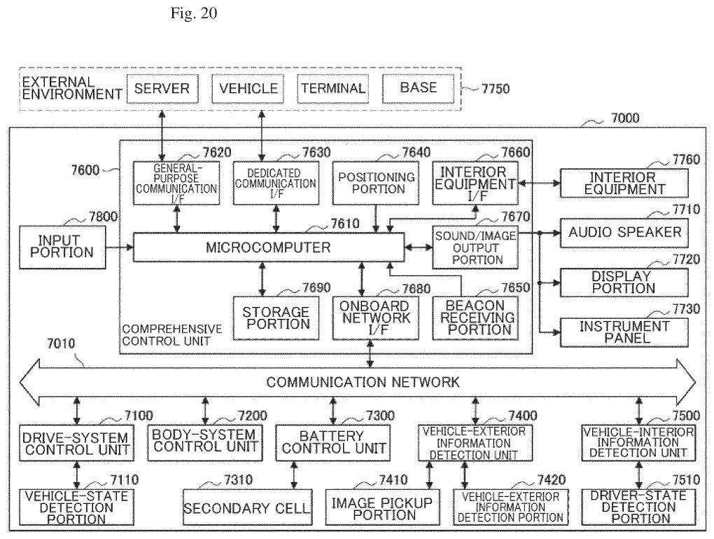

FIG. 20 is a block diagram illustrating a schematic configuration example of a vehicle control system 7000, which is an example of a movable-body control system to which the art according to this disclosure can be applied. The vehicle control system 7000 includes a plurality of electronic control units connected via a communication network 7010. In the example shown in FIG. 20, the vehicle control system 7000 includes a drive-system control unit 7100, a body-system control unit 7200, a battery control unit 7300, a vehicle-exterior information detection unit 7400, a vehicle-interior information detection unit 7500, and a comprehensive control unit 7600. The communication network 7010 that connects these plurality of control units may be an onboard communication network compliant with an arbitrary standard such as CAN (Controller Area Network), LIN (Local Interconnect Network), LAN (Local Area Network), FlexRay (registered trademark) or the like.

Each of the control units includes a microcomputer that executes operation processing in accordance with various programs, a storage portion that stores parameters and the like used for the program or various operations executed by the microcomputer, and a drive circuit that drives devices of various control targets. Each of the control units includes a network I/F for conducting communication with the other control units via the communication network 7010 and includes a communication I/F for conducting wired communication or wireless communication with devices, sensors, or the like inside and outside the vehicle. In FIG. 20, as a functional configuration of the comprehensive control unit 7600, a microcomputer 7610, a general-purpose communication I/F 7620, a dedicated communication I/F 7630, a positioning portion 7640, a beacon receiving portion 7650, an interior equipment I/F 7660, a sound/image output portion 7670, an onboard network I/F 7680, and a storage portion 7690 are illustrated. The other control units also include a microcomputer, a communication I/F, a storage portion and the like.

The drive-system control unit 7100 controls operations of devices related to a drive system of a vehicle in accordance with the various programs. For example, the drive-system control unit 7100 functions as a control device for a drive-force generating device that generates a drive force of a vehicle such as an internal combustion engine, a drive motor and the like, a drive-force transmission mechanism that transmits the drive force to wheels, a steering mechanism that adjusts a steering angle of the vehicle, a braking device that generates a braking force of the vehicle and the like. The drive-system control unit 7100 may have a function as a control device such as an ABS (Antilock Brake System) or an ESC (Electronic Stability Control) and the like.

To the drive-system control unit 7100, a vehicle-state detection portion 7110 is connected. The vehicle-state detection portion 7110 includes, for example, at least any one of a gyro sensor that detects an angular speed of an axial-rotation motion of a vehicle body, an acceleration sensor that detects acceleration of the brake or a sensor that detects an operation amount of an accelerator pedal, an operation amount of a brake pedal, a steering angle of a steering wheel, an engine rotation number, a rotation speed of the wheel or the like. The drive-system control unit 7100 executes the operation processing by using a signal input from the vehicle-state detection portion 7110 and controls the internal combustion engine, the drive motor, an electric power-steering device, a brake device or the like.

The body-system control unit 7200 controls operations of the various devices equipped in the vehicle body in accordance with the various programs. For example, the body-system control unit 7200 functions as a control device of a keyless entry system, a smart key system, a power-window device, or various lamps such as a head lamp, a back lamp, a brake lamp, a blinker, a fog lamp or the like. In this case, an electric wave emitted from a mobile device that replaces a key or a signal of various switches can be input to the body-system control unit 7200. The body-system control unit 7200 accepts the input of these electric waves or signals and controls a door-lock device, the power-window device, the lamps, and the like of a vehicle.

The battery control unit 7300 controls a secondary cell 7310, which is a power supply source of the drive motor in accordance with the various programs. For example, information such as a battery temperature, a battery output voltage, a battery residual capacity or the like is input to the battery control unit 7300 from a battery device including the secondary cell 7310. The battery control unit 7300 executes the operation processing by using these signals and executes temperature adjustment control of the secondary cell 7310 or control of a cooling device or the like provided in the battery device.

The vehicle-exterior information detection unit 7400 detects information outside the vehicle on which the vehicle control system 7000 is mounted. For example, to the vehicle-exterior information detection unit 7400, at least either one of an image pickup portion 7410 and a vehicle-exterior information detection portion 7420 is connected. The image pickup portion 7410 includes at least any one of a ToF (Time Of Flight) camera, a stereo camera, a monocular camera, an infrared camera and other cameras. The vehicle-exterior information detection portion 7420 includes at least any one of an environment sensor that detects a current weather or meteorological phenomenon or a peripheral-information detection sensor that detects other vehicles, an obstacle, a pedestrian and the like around the vehicle on which the vehicle control system 7000 is mounted, for example.

The environment sensor may be at least any one of a raindrop sensor that detects a rainy weather, a fog sensor that detects a fog, a sunshine sensor that detects a degree of sunshine, and a snow sensor that detects snowfall, for example. The peripheral-information detection sensor may be at least any one of an ultrasonic sensor, a radar device, and an LIDAR (Light Detection and Ranging, Laser Imaging Detection and Ranging) device. The image pickup portion 7410 and the vehicle-exterior information detection portion 7420 may be provided as an independent sensor or a device, respectively, or may be provided as a device in which a plurality of the sensors or devices are integrated.

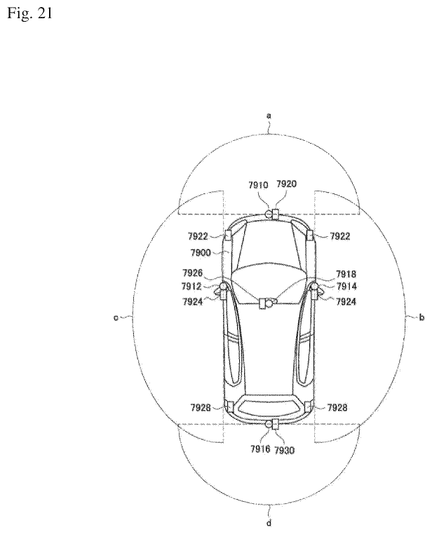

Here, FIG. 21 illustrates an example of installation positions of the image pickup portion 7410 and the vehicle-exterior information detection portion 7420. Image pickup portions 7910, 7912, 7914, 7916, 7918 are provided at least at one position in a front nose, a sideview mirror, a rear bumper, a back door, and an upper part of a windshield in a vehicle interior of the vehicle 7900, for example. The image pickup portion 7910 provided on the front nose and the image pickup portion 7918 provided on the upper part of the windshield in the vehicle interior acquire mainly images on the front of the vehicle 7900. The image pickup portions 7912, 7914 provided on the sideview mirrors acquire mainly images on the sides of the vehicle 7900. The image pickup portion 7916 provided on the rear bumper or the backdoor acquires mainly images on the rear of the vehicle 7900. The image pickup portion 7918 provided on the upper part of the windshield in the vehicle interior is used mainly for detection of a preceding vehicle, a pedestrian, an obstacle, a traffic signal, a traffic sign, a traffic lane or the like.

FIG. 21 illustrates an example of image-pickup ranges of the respective image pickup portions 7910, 7912, 7914, 7916. An image pickup range a indicates an image pickup range of the image pickup portion 7910 provided on the front nose, the image pickup ranges b, c indicate the image pickup ranges of the image pickup portions 7912, 7914 provided on the sideview mirrors, respectively, and the image pickup range d indicates the image pickup range of the image pickup portion 7916 provided on the rear bumper or the backdoor. By superimposing image data picked up by the image pickup portions 7910, 7912, 7914, 7916, for example, a downward image of the vehicle 7900 seen from above can be acquired.

Vehicle-exterior information detection portions 7920, 7922, 7924, 7926, 7928, 7930 provided on the front, the rear, the side, the corner, and the upper part of the windshield in the vehicle interior of the vehicle 7900 may be ultrasonic sensors or radar devices, for example. The vehicle-exterior information detection portions 7920, 7926, 7930 provided on the front nose, the rear bumper, the back door, and the upper part of the windshield in the vehicle interior of the vehicle 7900 may be LIDAR devices, for example. These vehicle-exterior information detection portions 7920 to 7930 are used mainly for detection of a preceding vehicle, a pedestrian, an obstacle or the like.

By returning to FIG. 20, the explanation will be continued. The vehicle-exterior information detection unit 7400 causes the image pickup portion 7410 to pick up an image outside the vehicle and receives picked-up image data. Moreover, the vehicle-exterior information detection unit 7400 receives the detection information from the vehicle-exterior information detection portion 7420 connected thereto. When the vehicle-exterior information detection portion 7420 is an ultrasonic sensor, a radar device, an LIDAR device or the like, the vehicle-exterior information detection unit 7400 transmits an ultrasonic wave, an electromagnetic wave or the like and receives the information of a reflected wave which was received. The vehicle-exterior information detection unit 7400 may execute object detection processing or distance detection processing of a human, a car, an obstacle, a sign, a letter on a road surface and the like on the basis of the received information. The vehicle-exterior information detection unit 7400 may execute environment recognition processing for recognition of rainfall, fog, a road surface situation, or the like on the basis of the received information. The vehicle-exterior information detection unit 7400 may calculate a distance to an object outside the vehicle on the basis of the received information.

Moreover, the vehicle-exterior information detection unit 7400 may execute image recognition processing for recognition of a human, a car, an obstacle, a sign, a letter on the road surface and the like or the distance detection processing on the basis of the received image data. The vehicle-exterior information detection unit 7400 may execute processing such as distortion correction, positioning, or the like to the received image data, synthesize the image data picked up by the different image pickup portion 7410, and generate a downward image or a panoramic image. The vehicle-exterior information detection unit 7400 may execute view-point conversion processing by using the image data picked up by the different image pickup portion 7410.

The vehicle-interior information detection unit 7500 detects information in the vehicle. To the vehicle-interior information detection unit 7500, a driver-state detection portion 7510 that detects a state of a driver is connected, for example. The driver-state detection portion 7510 may include a camera that picks up images of a driver, a biosensor that detects bio-information of the driver, a microphone that collects voice in the vehicle interior or the like. The biosensor is provided on a seat surface, a steering wheel or the like, for example, and detects bio-information of an occupant seated on a seat or a driver who grips the steering wheel. The vehicle-interior information detection unit 7500 may calculate a degree of fatigue or a degree of concentration of the driver or determine whether the driver is sleeping or not on the basis of the detected information input from the driver-state detection portion 7510. The vehicle-interior information detection unit 7500 may execute processing such as noise cancelling processing or the like to a signal of the collected voice.

The comprehensive control unit 7600 controls operations in general in the vehicle control system 7000 in accordance with the various programs. To the comprehensive control unit 7600, an input portion 7800 is connected. The input portion 7800 is realized by a device that can be input/operated by an occupant, such as a touch panel, a button, a microphone, a switch, a lever or the like, for example. To the comprehensive control unit 7600, data that was acquired by voice recognition of the voice input by the microphone may be input. The input portion 7800 may be a remote-control device using an infrared ray or other electric waves or external connection devices such as a mobile phone, a PDA (Personal Digital Assistant) or the like corresponding to the operation of the vehicle control system 7000. The input portion 7800 may be a camera, for example, and in that case, the occupant can input information by gesturing. Alternatively, data acquired by detecting a motion of a wearable device worn by the occupant may be input. Moreover, the input portion 7800 may include an input control circuit that generates an input signal on the basis of the information input by the occupant or the like by using the input portion 7800 described above and outputs it to the comprehensive control unit 7600. The occupant or the like inputs various types of data or instructs processing operations to the vehicle control system 7000 by operating this input portion 7800.

The storage portion 7690 may include a ROM (Read Only Memory) that stores various programs executed by the microcomputer and a RAM (Random Access Memory) that stores various parameters, calculation results, sensor values or the like. Moreover, the storage portion 7690 may be realized by a magnetic storage device such as an HDD (Hard Disc Drive) or the like, a semiconductor storage device, an optical storage device, a magneto-optical storage device or the like.

The general-purpose communication I/F 7620 is a general-purpose communication I/F that intermediates communication among various devices present in an external environment 7750. As the general-purpose communication I/F 7620, a cellular communication protocol such as GSM (registered trademark) (Global System of Mobile communications), WiMAX (registered trademark), LTE (registered trademark) (Long Term Evolution), LTE-A (LTE-Advanced) or the like or other wireless communication protocol such as wireless LAN (also referred to as Wi-Fi (registered trademark)), Bluetooth (registered trademark) or the like may be implemented. The general-purpose communication I/F 7620 may be connected to a device (an application server or a control server, for example) present on an external network (the Internet, a cloud network, or a company-specific network, for example) via a base station or an access point, for example. Moreover, the general-purpose communication I/F 7620 may be connected to a terminal present in a vicinity of a vehicle (a terminal of a driver, a pedestrian, or a shop or an MTC (Machine Type Communication) terminal, for example) by using a P2P (Peer To Peer) technology, for example.

The dedicated communication I/F 7630 is a communication I/F that supports the communication protocol designed with the purpose of use in a vehicle. As the dedicated communication I/F 7630, a standard protocol such as WAVE (Wireless Access in Vehicle Environment), which is a combination of a lower-level layer IEEE802.11p and an upper-level layer IEEE1609, DSRC (Dedicated Short Range Communications), a cellular communication protocol or the like may be implemented. The dedicated communication I/F 7630 typically accomplishes V2X communication, which is a concept including one or more of vehicle-to-vehicle (Vehicle to Vehicle) communication, road-to-vehicle (Vehicle to Infrastructure) communication, vehicle-to-home (Vehicle to Home) communication, and vehicle-to-pedestrian (Vehicle to Pedestrian) communication.

The positioning portion 7640 executes positioning by receiving a GNSS signal (GPS signal from a GPS (Global Positioning System) satellite) from a GNSS (Global Navigation Satellite System) satellite and generates position information including a latitude, a longitude, and an altitude of a vehicle, for example. The positioning portion 7640 may specify a current position by exchange of signals with a wireless access point or may acquire position information from a terminal such as a mobile phone, a PHS, or a smartphone having a positioning function.

The beacon receiving portion 7650 receives an electric wave or an electromagnetic wave transmitted from a wireless station or the like installed on a road or the like and acquires information such as the current position, traffic jam, road closure, required time or the like. The function of the beacon receiving portion 7650 may be included in the dedicated communication I/F 7630 described above.

The interior equipment I/F 7660 is a communication interface that intermediates connection between the microcomputer 7610 and various interior equipment 7760 present in the vehicle. The interior equipment I/F 7660 may establish wireless communication by using a wireless communication protocol such as the wireless LAN, Bluetooth (registered trademark), NFC (Near Field Communication), WUSB (Wireless USB) or the like. Moreover, the interior equipment I/F 7660 may establish wired connection such as a USB (Universal Serial Bus), an HDMI (registered trademark) (High-Definition Multimedia Interface) or MHL (Mobile High-definition Link) or the like through a connection terminal (and a cable, if necessary), not shown. The interior equipment 7760 may include at least any one of a mobile device or a wearable device of the occupant or information devices carried in or mounted in the vehicle, for example. Moreover, the interior equipment 7760 may include a navigation device that performs route search to an arbitrary destination. The interior equipment I/F 7660 exchanges control signals or data signals with the interior equipment 7760.

The onboard network I/F 7680 is an interface that intermediates communication between the microcomputer 7610 and the communication network 7010. The onboard network I/F 7680 transmits/receives a signal and the like in accordance with a predetermined protocol supported by the communication network 7010.

The microcomputer 7610 in the comprehensive control unit 7600 controls the vehicle control system 7000 in accordance with the various programs on the basis of the information acquired via at least any one of the general-purpose communication I/F 7620, the dedicated communication I/F 7630, the positioning portion 7640, the beacon receiving portion 7650, the interior equipment I/F 7660, and the onboard network I/F 7680. For example, the microcomputer 7610 may calculate a control target value of a drive-force generating device, a steering mechanism, or a braking device on the basis of the acquired information inside and outside the vehicle and output a control instruction to the drive-system control unit 7100. For example, the microcomputer 7610 may execute coordinated control for the purpose of realization of the function of ADAS (Advanced Driver Assistance System) including collision avoidance or impact relaxation of the vehicle, follow-up driving based on an inter-vehicular distance, vehicle-speed maintained driving, a collision alarm of the vehicle, a lane-departure alarm of the vehicle or the like. Furthermore, the microcomputer 7610 may execute the coordinated control for the purpose of automated driving or the like, which is automated driving without depending on an operation by a driver, by controlling the drive-force generating device, the steering mechanism, the braking device, or the like on the basis of the acquired information in the periphery of the vehicle.

The microcomputer 7610 may generate three-dimensional distance information between the vehicle and the object such as a construction, a human being and the like in the periphery on the basis of the information acquired via at least any one of the general-purpose communication I/F 7620, the dedicated communication I/F 7630, the positioning portion 7640, the beacon receiving portion 7650, the interior equipment I/F 7660, and the onboard network I/F 7680 and generate local map information including peripheral information of the current position of the vehicle. Moreover, the microcomputer 7610 may generate a signal for alarm by predicting a danger such as a collision of the vehicle, approach of a pedestrian or the like, entry to a closed road, and the like on the basis of the acquired information. The signal for alarm may be such a signal that generates an alarm sound or lights an alarm lamp.

The sound/image output portion 7670 transmits an output signal of at least either one of sound and image to an output device capable of notifying information visually or audibly to the occupant of the vehicle or outside the vehicle. In the example in FIG. 20, an audio speaker 7710, a display portion 7720, and an instrument panel 7730 are exemplified as output devices. The display portion 7720 may include at least any one of an onboard display and a head-up display, for example. The display portion 7720 may have an AR (Augmented Reality) display function. The output device may be other devices, other than these devices, such as a headphone, a wearable device such as a glasses-type display worn by the occupant, a projector, a lamp or the like. When the output device is a display device, the display device visually displays the result acquired by various types of processing executed by the microcomputer 7610 or the information received from the other control units in various formats such as a text, an image, a table, a graph, and the like. Moreover, when the output device is a sound output device, the sound output device converts an audio signal made of reproduced sound data, audio data or the like to an analogue signal and audibly outputs it.

In the example shown in FIG. 20, at least two control units connected via the communication network 7010 may be integrated as one control unit. Alternatively, each control unit may be constituted by a plurality of control units. Moreover, the vehicle control system 7000 may include another control unit, not shown. Furthermore, in the explanation above, some or all the functions borne by any one of the control units may be provided in another control unit. That is, as long as information is transmitted/received via the communication network 7010, predetermined calculation processing may be executed by any one of the control units. Similarly, the sensor or the device connected to any one of the control units may be connected to another control unit, and a plurality of the control units may mutually transmit/receive detection information via the communication network 7010.

The computer program for realizing each of the functions of the light detection device 1 according to this embodiment described by using FIG. 1 and the like may be implemented in any one of the control units. Moreover, a computer-readable recording medium in which the computer programs as above are stored may be provided. The recording medium is a magnetic disk, an optical disk, a magneto-optical disk, a flash memory or the like, for example. Moreover, the computer programs described above may be distributed via the network, for example, without using the recording medium.

In the vehicle control system 7000 described above, the light detection device 1 according to this embodiment explained by using FIG. 1 and the like can be applied to the comprehensive control unit 7600 as an application example shown in FIG. 20.

Moreover, at least some constituent elements of the light detection device 1 described by using FIG. 1 and the like may be realized in a module for the comprehensive control unit 7600 shown in FIG. 20 (an integrated circuit module constituted by one die, for example). Alternatively, the light detection device 1 explained by using FIG. 1 may be realized by a plurality of the control units of the vehicle control system 7000 shown in FIG. 20.

This art can employ configurations as follows:

(1) A light detection device including
a photoelectric conversion region having a plurality of pixels, and
a light guide region that is laminated on the photoelectric conversion region and controls a propagation direction of light to the photoelectric conversion region, in which
the light guide region has a pixel guide region having nanostructures for each of the plurality of pixels, and
the pixel guide region controls the propagation direction of the light in a light amount within an opening range according to an image height.

(2) The light detection device described in (1), in which
the plurality of pixel guide regions corresponding to the plurality of pixels control the opening range by changing at least any one of a pitch diameter of the nanostructures, a pitch interval between the nanostructures, a gap interval between the nanostructures, and a number of the nanostructures in accordance with the image height.

(3) The light detection device described in (1) or (2), in which
in the pixel guide region, the higher the image height is, the larger the opening range is enlarged, and the lower the image height is, the smaller the opening range is reduced.

(4) A light detection device, including
a photoelectric conversion region having a plurality of pixels, and
a light guide region disposed closer to a light incident direction side than the photoelectric conversion region and controls a propagation direction of light to the photoelectric conversion region, in which
the light guide region has a pixel guide region having nanostructures for each of the plurality of pixels, and
each of the plurality of pixel guide regions corresponding to the plurality of pixels controls an opening range according to a light amount of the light incident to the corresponding pixel guide region by varying at least any one of a pitch diameter of the nanostructures, a pitch interval between the nanostructures, a gap interval between the nanostructures, and a number of the nanostructures in accordance with an image height.

(5) The light detection device described in any one of (1) to (4), in which
in the pixel guide region, the higher the image height is, the larger amount of light is propagated to the photoelectric conversion region, and the lower the image height is, the smaller amount of light is propagated to the photoelectric conversion region.

(6) The light detection device described in any one of (1) to (5), in which
the photoelectric conversion region has a plurality of color pixels for each of the plurality of pixels,
the light guide region has the pixel guide region for each of the plurality of color pixels, and
the pixel guide region controls the propagation direction of the light in the light amount according to a wavelength of incident light and the image height.

(7) The light detection device described in (6), in which
the pixel guide region varies a change rate of an incident light amount with respect to a change in the image height depending on a wavelength of the incident light.

(8) The light detection device described in (7), in which
each of the plurality of pixel guide regions corresponding to the plurality of color pixels included in one pixel controls the opening range on the basis of a difference in the number of the color pixels by color in the one pixel.

(9) The light detection device described in (8), in which
the smaller the number of the color pixels by color in the one pixel to which the pixel guide region corresponds, the larger the opening range is enlarged so that a larger light amount is transmitted.

(10) The light detection device described in any one of (6) to (9), in which
a color filter region disposed correspondingly to the plurality of color pixels is provided between the light guide region and the photoelectric conversion region,
the color filter region has a plurality of color filter portions for one pixel, and
the pixel guide region controls the opening range on the basis of the difference in the number by color of the plurality of color filter portions.

(11) The light detection device described in any one of (1) to (10), in which
the plurality of pixel guide regions corresponding to the plurality of pixels have different materials of the nanostructures in accordance with the image height.

(12) The light detection device described in (11), in which
the nanostructures have
a plurality of columnar members disposed separately from each other along a light incident surface, and
a base member that covers a periphery of the plurality of columnar members,
the plurality of pixel guide regions corresponding to the plurality of pixels vary a material of at least either one of the columnar member and the base member in accordance with the image height.

(13) The light detection device described in any one of (1) to (12), in which
in the plurality of pixel guide regions corresponding to the plurality of pixels, pupil correction to the incident light is performed at least in some of the pixel guide regions.

(14) The light detection device described in (13), in which
the closer to a peripheral side than a center side in the light guide region the pixel guide region is located, the larger a pupil correction amount is set.

(15) The light detection device described in (14), in which
the pupil correction is performed by shifting the pixel guide region in the light guide region along the light incident surface with respect to the corresponding pixel in the photoelectric conversion region, and
the closer to the peripheral side than the center side in the light guide region the pixel guide region is located, the larger amount by which the pixel guide region in the light guide region is shifted is set with respect to the corresponding pixel in the photoelectric conversion region.

(16) The light detection device described in (10), in which
the pupil correction is performed by shifting the pixel guide region in the light guide region along the light incident surface with respect to the corresponding color filter portion in the color filter region, and
the closer to the peripheral side than the center side in the light guide region the pixel guide region is located, the larger amount by which the pixel guide region in the light guide region is shifted is set with respect to the corresponding color filter portion in the color filter region.

(17) The light detection device described in (14), in which
the light guide region has
a first light control portion having first nanostructures and
a second light control portion laminated on the first light control portion and having second nanostructures,
the first light control portion and the second light control portion have pixel guide regions having nanostructures for each of the plurality of pixels,
the pupil correction is performed by shifting the pixel guide region in the first light control portion along the light incident surface with respect to the corresponding pixel guide region in the second light control portion, and
the closer to the peripheral side than the center side in the light guide region the pixel guide region is located, the larger amount by which the pixel guide region in the first light control portion is shifted is set with respect to the corresponding pixel guide region in the second light control portion.

(18) A light detection device comprising:
a pixel array including a plurality of pixel units, at least one pixel unit of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.

(19) The light detection device according to (18), wherein
the at least one characteristic of the nanostructures corresponds to a diameter of the nanostructures, a pitch of the nanostructures, a gap between two of the nanostructures, and a number of the nanostructures.

(20) The light detection device according to one or more of (18 to 19), wherein
an opening range of each pixel unit of the at least one pixel unit varies based on the at least one characteristic of the nanostructures.

(21) The light detection device according to (20), wherein
the opening range becomes larger as a distance from a center of the pixel array increases.

(22) The light detection device according to one or more of (18 to 21), wherein
an amount of light guided by the light guide region to the photoelectric conversion region increases as a distance from a center of the pixel array increases.

(23) The light detection device according to one or more of (18 to 22), wherein
each pixel unit of the at least one pixel unit includes a color filter; and
a propagation direction of light passing through the color filter varies based on wavelength and the nanostructures.

(24) The light detection device according to (23), wherein
a change rate of opening ranges of each pixel unit of the at least one pixel unit is based on wavelengths passed by the color filter.

(25) The light detection device according to (24), wherein
the change rate for pixel units sensing green wavelengths is less than the change rate for pixel units sensing red or blue wavelengths.

(26) The light detection device according to (25), wherein
sizes of opening ranges for pixel units with color filters passing a first range of wavelengths are different from sizes of opening ranges for pixel units with color filters passing a second range of wavelengths different than the first range of wavelengths.

(27) The light detection device according to (23), wherein for each pixel unit of the at least one pixel unit
the color filter is disposed between the light guide region and the photoelectric conversion region.

(28) The light detection device according to one or more of (18 to 27), wherein
the at least one characteristic of the nanostructures corresponds to a material of the nanostructures.

(29) The light detection device according to (28), wherein each of the nanostructures includes:
a plurality of columnar members disposed separately from each other; and
a base member that covers a periphery of the plurality of columnar members,
wherein, for each pixel unit of the at least one pixel unit, a material of the plurality of columnar members or the base member is based on the position of the pixel unit in the pixel array.

(30) The light detection device according to one or more of (18 to 29), wherein, for
each pixel unit of the at least one pixel unit, a central axis of the photoelectric conversion region is offset from a central axis of the light guide region by a pupil correction amount.

(31) The light detection device according to (30), wherein
the pupil correction amount becomes larger as a distance away from a center of the pixel array increases.

(32) The light detection device according to (31), wherein
the offset is caused by shifting the light guide region with respect to the photoelectric conversion region.

(33) The light detection device according to (27), wherein, for each pixel unit of the at least one pixel unit, a central axis of the photoelectric conversion region is offset from a central axis of the light guide region by a pupil correction amount.

(34) The light detection device according to one or more of (31 to 32), wherein, for each pixel unit of the at least one pixel unit, the light guide region includes:
a first light guide portion having a first nanostructures; and
a second light guide portion laminated on the first light guide portion and having a second nanostructures,
wherein the offset corresponds to the first light guide portion being shifted with respect to the second light guide portion by the pupil correction amount.

(35) The light detection device according to one or more of (18 to 34), wherein
at least one of the plurality of pixel units includes a first pixel and a second pixel adjacent to the first pixel,
the first pixel comprises a first photoelectric conversion region and a first light guide region,
the second pixel comprises a second photoelectric conversion region, and
the first light guide region guides light to the second photoelectric conversion region.

(36) An image sensor, comprising:
a pixel array including a plurality of pixel units, at least one of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.

(37) An electronic device, comprising:
a processing circuit; and
a light detecting device, including:
a pixel array including a plurality of pixel units, at least one pixel unit of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.

The modes of this disclosure are not limited to each of the embodiments described above but include various variations that could have been conceived of by those skilled in the art, and the effect of this disclosure is not limited to the aforementioned contents, either. That is, various additions, changes, and partial deletions are possible within a range not departing from the conceptual idea and gist of this disclosure derived from the contents and the equivalents thereof prescribed in the appended claims.

### REFERENCE SIGNS LIST

1 Light detection device
2 Pixel array portion
3 Vertical drive circuit
4 Column-signal processing circuit
5 Horizontal drive circuit
6 Output circuit
7 Control circuit
10 Adjacent pixel
10 Pixel unit
10c Color pixel
11 Photoelectric conversion region
12 Lens
13 Light guide region (color splitter)
13a First light control portion
13b Second light control portion
14 Nanostructures (Nanostructual body)
14b Base member
14p Pillar portion
15 Color filter region
16 Opening range
17 Pixel guide region
18 Light-shielding wall
19 Light-shielding wall
20 Insulation layer

What is claimed is:

1. A light detection device, comprising:
a pixel array including a plurality of pixel units, at least one pixel unit of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.

2. The light detection device according to claim 1, wherein
the at least one characteristic of the nanostructures corresponds to a diameter of the nanostructures, a pitch of the nanostructures, a gap between two of the nanostructures, and a number of the nanostructures.

3. The light detection device according to claim 1, wherein
an opening range of each pixel unit of the at least one pixel unit varies based on the at least one characteristic of the nanostructures.

4. The light detection device according to claim 3, wherein
the opening range becomes larger as a distance from a center of the pixel array increases.

5. The light detection device according to claim 1, wherein
an amount of light guided by the light guide region to the photoelectric conversion region increases as a distance from a center of the pixel array increases.

6. The light detection device according to claim 1, wherein
each pixel unit of the at least one pixel unit includes a color filter; and
a propagation direction of light passing through the color filter varies based on wavelength and the nanostructures.

7. The light detection device according to claim 6, wherein
a change rate of opening ranges of each pixel unit of the at least one pixel unit is based on wavelengths passed by the color filter.

8. The light detection device according to claim 7, wherein
the change rate for pixel units sensing green wavelengths is less than the change rate for pixel units sensing red or blue wavelengths.

9. The light detection device according to claim 8, wherein
sizes of opening ranges for pixel units with color filters passing a first range of wavelengths are different from sizes of opening ranges for pixel units with color filters passing a second range of wavelengths different than the first range of wavelengths.

10. The light detection device according to claim 6, wherein for each pixel unit of the at least one pixel unit
the color filter is disposed between the light guide region and the photoelectric conversion region.

11. The light detection device according to claim 1, wherein
the at least one characteristic of the nanostructures corresponds to a material of the nanostructures.

12. The light detection device according to claim 11, wherein each of the nanostructures includes:
a plurality of columnar members disposed separately from each other; and
a base member that covers a periphery of the plurality of columnar members,
wherein, for each pixel unit of the at least one pixel unit, a material of the plurality of columnar members or the base member is based on the position of the pixel unit in the pixel array.

13. The light detection device according to claim 1, wherein, for each pixel unit of the at least one pixel unit, a central axis of the photoelectric conversion region is offset from a central axis of the light guide region by a pupil correction amount.

14. The light detection device according to claim 13, wherein
the pupil correction amount becomes larger as a distance away from a center of the pixel array increases.

15. The light detection device according to claim 14, wherein
the offset is caused by shifting the light guide region with respect to the photoelectric conversion region.

16. The light detection device according to claim 10, wherein, for each pixel unit of the at least one pixel unit, a central axis of the photoelectric conversion region is offset from a central axis of the light guide region by a pupil correction amount.

17. The light detection device according to claim 14, wherein, for each pixel unit of the at least one pixel unit, the light guide region includes:
a first light guide portion having a first nanostructures; and
a second light guide portion laminated on the first light guide portion and having a second nanostructures,
wherein the offset corresponds to the first light guide portion being shifted with respect to the second light guide portion by the pupil correction amount.

18. The light detection device according to claim 1, wherein
the at least one pixel unit includes a first pixel and a second pixel adjacent to the first pixel,
the first pixel comprises a first photoelectric conversion region and a first light guide region,
the second pixel comprises a second photoelectric conversion region, and
the first light guide region guides light to the second photoelectric conversion region.

19. An image sensor, comprising:
a pixel array including a plurality of pixel units, at least one of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.

20. An electronic device, comprising:
a processing circuit; and
a light detecting device, including:
a pixel array including a plurality of pixel units, at least one pixel unit of the plurality of pixel units including a photoelectric conversion region and a light guide region that guides light to the photoelectric conversion region,
wherein for each pixel unit of the at least one pixel unit:
the light guide region includes nanostructures that direct light to the photoelectric conversion region; and
the nanostructures have at least one characteristic that varies based on a position of the pixel unit in the pixel array.
